(19) United States
(12) Patent Application Publication
(10) Pub. No.: US 2026/0230103 A1
(43) Pub. Date: Aug. 6, 2026

(54) WIRELESS COMMUNICATION DEVICE AND METHOD

(71) Applicant: NEC Corporation, Tokyo (JP)

(72) Inventor: Masaaki TANIO, Tokyo (JP)

(73) Assignee: NEC Corporation, Tokyo (JP)

(21) Appl. No.: 19/454,615

(22) Filed: Jan. 21, 2026

(30) Foreign Application Priority Data
Feb. 6, 2025 (JP) 2025-018242

(51) Int. Cl. H04B 1/40; H03M 3/00; H04B 1/04

(52) U.S. Cl. CPC H04B 1/40; H03M 3/39; H04B 1/0475

(57) ABSTRACT

A wireless communication device includes a band limiting unit for passing a frequency component corresponding to an nth (n is an integer equal to or greater than two) Nyquist zone in an input signal based on a signal delta sigma modulated by a delta sigma modulation unit, and a feedback signal forming unit that includes a frequency conversion unit for converting a frequency component that has passed through the band limiting unit into a frequency corresponding to a first Nyquist zone, and forms a feedback signal used for learning of a distortion model to which an output signal of the delta sigma modulation unit is input and outputs a distortion reflecting signal reflecting a distortion component of the first Nyquist zone corresponding to a distortion component of an nth Nyquist zone in the input signal, based on the frequency component that has passed through the band limiting unit.

### INCORPORATION BY REFERENCE

This application is based upon and claims the benefit of priority from Japanese patent application No. 2025-018242, filed on Feb. 6, 2025, the disclosure of which is incorporated herein in its entirety by reference.

### TECHNICAL FIELD

The present disclosure relates to a wireless communication device and a wireless communication method.

### BACKGROUND ART

Communication using delta sigma modulation has been proposed (e.g., WO 2016/103981 A1).

Since the bit rate of the delta sigma modulation is limited, there is a limit to the carrier frequency that can be achieved. For this reason, it is difficult to directly deal with recent communication using a millimeter wave or a terahertz wave by delta sigma modulation.

On the other hand, there has been proposed a method for achieving a high carrier frequency output by utilizing a frequency component exceeding the Nyquist rate (e.g., J. Zhang and N. Suematsu, “40 GHz-Band Direct Digital RF Modulator Using the 2nd Image Component of 1-Bit Delta-Sigma Modulated Signal,” 2022 Asia-Pacific Microwave Conference (APMC), Yokohama, Japan, 2022, pp. 496 to 498). However, there is a problem that waveform distortion due to power reflection generated in the band pass filter deteriorates signal quality after filtering.

Meanwhile, a technique for suppressing distortion occurring in a signal in a process of transmitting a delta sigma modulated signal has been proposed (e.g., WO 2023/021625).

### SUMMARY

However, in the technique disclosed in WO 2023/021625, it is assumed that a first Nyquist frequency is used, and there is a possibility that a feedback signal for learning the distortion occurring in the Nyquist zone of equal to or greater than the second Nyquist zone cannot be formed.

An example object of the present disclosure is to provide a wireless communication device and a wireless communication method capable of forming a feedback signal for learning distortion occurring in a Nyquist zone equal to or greater than a second Nyquist zone of a delta sigma modulated signal. It should be noted that the object is merely one of a plurality of objects to be achieved by a plurality of example embodiments disclosed herein. The other objects or problems and novel features will be apparent from the description of the present specification or the accompanying drawings.

A wireless communication device according to an example aspect of the present disclosure includes a band limiting unit for passing a frequency component corresponding to an nth (n is an integer equal to or greater than two) Nyquist zone in an input signal based on a signal delta sigma modulated by a delta sigma modulation unit, and a feedback signal forming unit that includes a frequency conversion unit for converting a frequency component that has passed through the band limiting unit into a frequency component with a frequency corresponding to a first Nyquist zone, and forms a feedback signal used for learning of a distortion model to which an output signal of the delta sigma modulation unit is input and outputs a distortion reflecting signal reflecting a distortion component of the first Nyquist zone corresponding to a distortion component of an nth Nyquist zone in the input signal, based on the frequency component that has passed through the band limiting unit.

A method according to an example aspect of the present disclosure is a method executed by a feedback signal forming device, the method including executing band limiting processing of passing a frequency component corresponding to an nth (n is an integer equal to or greater than two) Nyquist zone in an input signal based on a signal delta sigma modulated in delta sigma modulation processing, and executing feedback signal forming processing of forming, based on the passed frequency component, a feedback signal used for learning of a distortion model to which an output signal of the delta sigma modulation processing is input and that outputs a distortion reflecting signal reflecting a distortion component of a first Nyquist zone corresponding to a distortion component of the nth Nyquist zone in the input signal, in which the feedback signal forming processing includes frequency conversion processing of converting the passed frequency component to a frequency component with a frequency corresponding to the first Nyquist zone.

According to the present disclosure, a wireless communication device and a wireless communication method capable of forming a feedback signal for learning distortion occurring in a Nyquist zone equal to or greater than a second Nyquist zone of a delta sigma modulated signal can be provided.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a block diagram illustrating an example of a wireless communication device of the present disclosure;

FIG. 2 is a flowchart illustrating an example of a processing operation of the wireless communication device of the present disclosure;

FIG. 3 is a block diagram illustrating an example of a feedback signal forming unit of the present disclosure;

FIG. 4 is a diagram provided for explaining a feedback signal forming processing of the present disclosure;

FIG. 5 is a diagram provided for explaining a feedback signal forming processing of the present disclosure;

FIG. 6 is a block diagram illustrating another example of the feedback signal forming unit of the present disclosure;

FIG. 7 is a diagram illustrating a more specific configuration of another example of the feedback signal forming unit of the present disclosure;

FIG. 8 is a diagram provided for explaining a feedback signal forming processing of the present disclosure;

FIG. 9 is a diagram provided for explaining the feedback signal forming processing of the present disclosure;

FIG. 10 is a diagram provided for explaining the feedback signal forming processing of the present disclosure;

FIG. 11 is a block diagram illustrating another example of the wireless communication device of the present disclosure;

FIG. 12 is a block diagram illustrating an example of a delta sigma modulation unit of the present disclosure;

FIG. 13 is a block diagram illustrating an example of a model processing unit of the present disclosure;

FIG. 14 is a block diagram illustrating an example of a learning unit of the present disclosure;

FIG. 15 is a block diagram illustrating an example of a system of the present disclosure; and

FIG. 16 is a diagram illustrating a configuration example of a wireless communication device.

### EXAMPLE EMBODIMENTS

Hereinafter, example embodiments will be described with reference to the drawings. In the present disclosure, the drawings can be associated with one or more example embodiments. In addition, each element of the drawings can be applied to one or more example embodiments. In addition, in the example embodiments, the same or equivalent elements are denoted by the same reference signs, and repeated description will be omitted.

### First Example Embodiment

### Configuration Example of Wireless Communication Device

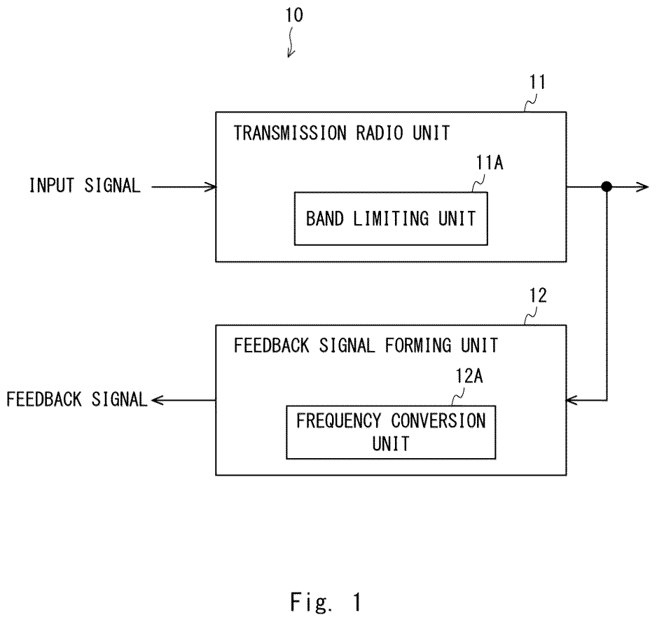

FIG. 1 is a block diagram illustrating an example of a wireless communication device of the present disclosure. In FIG. 1, a wireless communication device 10 includes a transmission radio unit 11 including a band limiting unit 11A and a feedback signal forming unit 12 including a frequency conversion unit 12A.

The transmission radio unit 11 performs transmission radio processing on the input signal and outputs a signal after the transmission radio processing. The signal after the transmission radio processing is transmitted to the device of the communication partner via an antenna (not illustrated). The signal after the transmission radio processing is input to the feedback signal forming unit 12.

An input signal to the transmission radio unit 11 (band limiting unit 11A) is a signal based on a signal that has been delta sigma modulated by a delta sigma modulation unit (not illustrated) operating in the first Nyquist zone. For example, in a case where the wireless communication device 10 includes a delta sigma modulation unit (not illustrated), the input signal to the transmission radio unit 11 (band limiting unit 11A) may be a signal obtained by passing a delta sigma modulated signal through an electric transmission line (e.g., a metal wire) in the wireless communication device 10. Alternatively, in a case where the delta sigma modulation unit (not illustrated) is included in another wireless communication device (not illustrated), the input signal to the transmission radio unit 11 (band limiting unit 11A) may be a signal received by the wireless communication device 10 after the delta sigma modulated signal is wirelessly transmitted from another wireless communication device (not illustrated). Alternatively, in a case where the delta sigma modulation unit (not illustrated) is included in an optical communication device (not illustrated), the input signal to the transmission radio unit 11 (band limiting unit 11A) may be an electrical signal obtained by performing optical-electrical conversion on an optical signal, the optical signal being received by the wireless communication device 10 after the delta sigma modulated signal is electro-optically converted to an optical signal and optically transmitted from the optical communication device (not illustrated).

The band limiting unit 11A passes a frequency component corresponding to an nth (n is an integer equal to or greater than two) Nyquist zone in the input signal and outputs the frequency component. The band limiting unit 11A is, for example, a band pass filter. The frequency component is transmitted to a device of a communication partner via an antenna (not illustrated). Furthermore, the frequency component is input to the feedback signal forming unit 12.

The feedback signal forming unit 12 forms a feedback signal used for learning of the “distortion model” based on the frequency component that has passed through the band limiting unit 11A. For example, an output signal of a delta sigma modulation unit (not illustrated) is input to the distortion model. Then, the distortion model outputs a signal (hereinafter, it may be referred to as a “distortion reflecting signal”) reflecting the distortion component (alternatively, an approximate value of the distortion component) of the first Nyquist zone corresponding to the distortion component of the nth Nyquist zone in the input signal to the transmission radio unit 11 (band limiting unit 11A). The distortion reflecting signal is a signal (or an estimated signal) obtained by approximating a signal obtained in a case where a frequency component corresponding to the nth Nyquist zone in the input signal to the transmission radio unit 11 (band limiting unit 11A) is frequency converted into the first Nyquist zone. As described later, a distortion component signal is formed based on an output signal of a delta sigma modulation unit (not illustrated) and a distortion reflecting signal output from a learned distortion model, and delta sigma modulation is performed using the distortion component signal and a transmission signal. As a result, distortion occurring in an input signal (in particular, the frequency component of the nth Nyquist zone) to the transmission radio unit 11 (band limiting unit 11A) can be suppressed. Here, the distortion component signal is a signal (or an estimated signal) obtained by approximating a signal obtained in a case where a distortion component included in a frequency component corresponding to the nth Nyquist zone in the input signal to the transmission radio unit 11 (band limiting unit 11A) is frequency converted into the first Nyquist zone.

The frequency conversion unit 12A converts the frequency component that has passed through the band limiting unit 11A into a frequency corresponding to the first Nyquist zone. Here, in the learning processing of the distortion model, the distortion reflecting signal that the distortion model to be learned receives the output signal of the delta sigma modulation unit (not illustrated) and outputs based on the output signal is compared with the feedback signal. As described above, since the delta sigma modulation unit (not illustrated) operates in the first Nyquist zone, the feedback signal to be compared with the distortion reflecting signal obtained from the output signal of the delta sigma modulation unit (not illustrated) is desirably a signal having a frequency corresponding to the first Nyquist zone. As described above, since the frequency conversion unit 12A of the feedback signal forming unit 12 converts the frequency component that has passed through the band limiting unit 11A into the frequency corresponding to the first Nyquist zone, a suitable feedback signal can be formed. As a result, the accuracy of the learning processing of the distortion model can be improved. Furthermore, distortion can be suppressed with high accuracy by performing delta sigma modulation based on the distortion reflecting signal output from the distortion model learned with high accuracy. As a result, communication quality can be improved.

### Operation Example of Wireless Communication Device

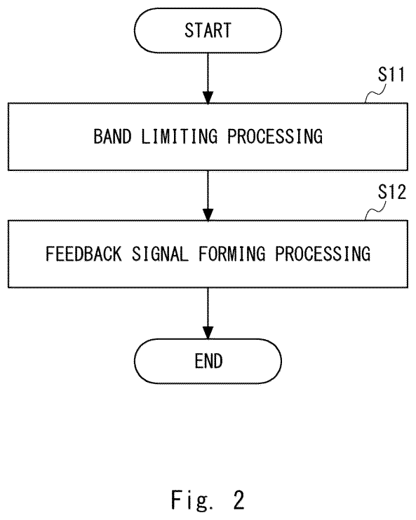

FIG. 2 is a flowchart illustrating an example of a processing operation of the wireless communication device of the present disclosure.

The band limiting unit 11A executes band limiting processing of passing a frequency component corresponding to an nth (n is an integer equal to or greater than two) Nyquist zone of the input signal (step S11). The input signal is a signal based on a signal delta sigma modulated by a delta sigma modulation unit (not illustrated) operating in the first Nyquist zone.

The feedback signal forming unit 12 executes feedback signal forming processing of forming a feedback signal used for learning of the “distortion model” based on the frequency component passed in the band limiting processing (step S12). The distortion model is a model to which the output signal of the delta sigma modulation processing is input, and which outputs a distortion reflecting signal reflecting the distortion component (alternatively, an approximate value of the distortion component) of the first Nyquist zone corresponding to the distortion component of the nth Nyquist zone in the input signal. The feedback signal forming processing includes a frequency conversion processing of converting the frequency component passed in the band limiting processing into a frequency corresponding to the first Nyquist zone.

As described above, according to the first example embodiment, in the wireless communication device 10, the band limiting unit 11A allows a frequency component corresponding to the nth (n is an integer equal to or greater than two) Nyquist zone of the input signal to pass through. The feedback signal forming unit 12 forms a feedback signal used for learning of the “distortion model” based on the frequency component that has passed through the band limiting unit 11A. The feedback signal forming unit 12 includes a frequency conversion unit 12A. The frequency conversion unit 12A converts the frequency component that has passed through the band limiting unit 11A into a frequency corresponding to the first Nyquist zone.

With the configuration of the wireless communication device 10, it is possible to form a feedback signal suitable for learning distortion occurring in the Nyquist zone equal to or more than the second Nyquist zone of the delta sigma modulated signal.

### Second Example Embodiment

A second example embodiment relates to a variation of the configuration of the feedback signal forming unit.

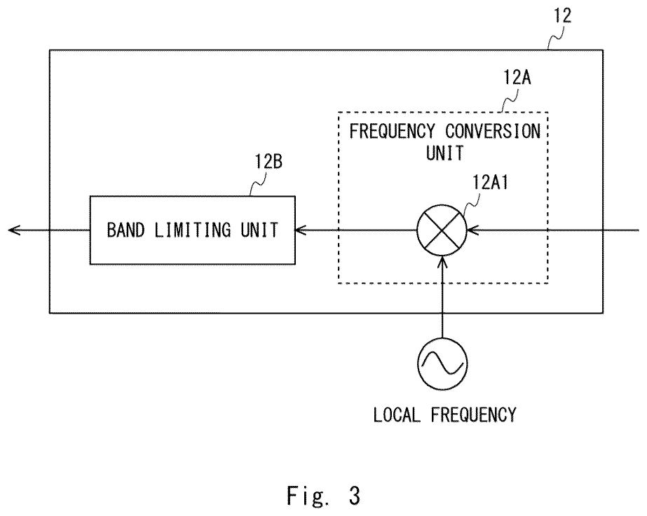

FIG. 3 is a block diagram illustrating an example of a feedback signal forming unit of the present disclosure. In FIG. 3, the feedback signal forming unit 12 includes a frequency conversion unit 12A and a band limiting unit 12B. The frequency conversion unit 12A includes a mixer 12A1.

If n is an even number, the frequency conversion unit 12A (mixer 12A1) performs frequency conversion on the frequency component that has passed through the band limiting unit 11A such that the frequency of the image component among the frequency components becomes the target frequency of the first Nyquist zone. For example, in a case where n is an even number, the sample rate of the delta sigma modulation is Fs, and the carrier frequency of the first Nyquist zone of the delta sigma modulated signal is Fc, the local frequency of the frequency conversion unit 12A (mixer 12A1) is n×Fs.

The band limiting unit 12B passes a frequency component corresponding to the passing band including the target frequency of the first Nyquist zone among the frequency components frequency converted by the frequency conversion unit 12A (mixer 12A1). The band limiting unit 12B is, for example, a band pass filter.

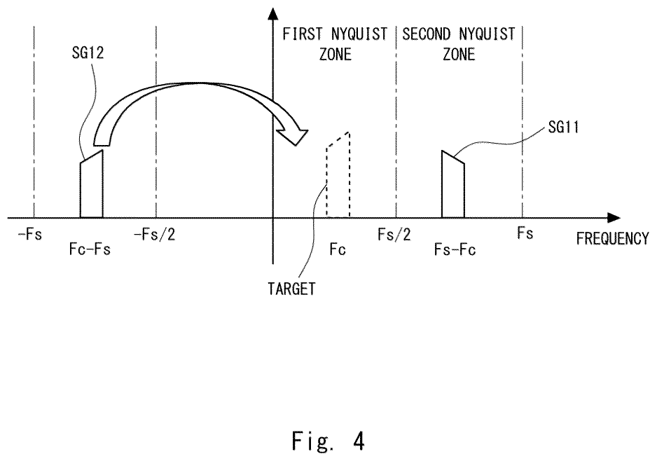

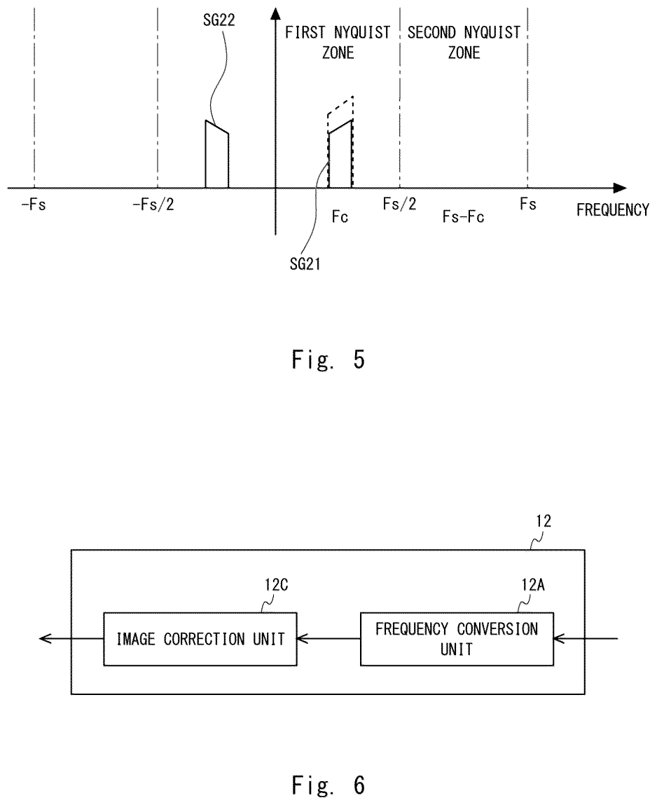

FIGS. 4 and 5 are diagrams provided for explaining a feedback signal forming processing. FIGS. 4 and 5 illustrate a case where n=2. The inclination of the upper side of the signal illustrated in FIGS. 4 and 5 represents the frequency characteristic of the signal. That is, the frequency characteristics of a certain signal and the image of the signal are inverted from each other in the frequency domain. In addition, the frequency characteristics of the frequency component of the nth Nyquist zone in which n is an odd number and the frequency component of the nth Nyquist zone in which n is an even number are inverted from each other in the frequency domain.

In FIG. 4, the signal SG11 and the signal SG12 are frequency components that have passed through the band limiting unit 11A. The signal SG12 is an image of the signal SG11. The frequency conversion unit 12A (mixer 12A1) up-converts the frequency of the signal SG12 to be the target frequency of the first Nyquist zone. As a result, a signal SG21 and a signal SG22 illustrated in FIG. 5 are obtained.

Then, the band limiting unit 12B passes the signal SG21 and the signal SG22, and cuts off the frequency components other than the passing band.

If n is an odd number, the frequency conversion unit 12A (mixer 12A1) may perform frequency conversion on the frequency component that has passed through the band limiting unit 11A such that the frequency of the frequency component becomes the target frequency of the first Nyquist zone. For example, if n is an odd number, the sample rate of the delta sigma modulation is Fs, and the carrier frequency of the first Nyquist zone of the delta sigma modulated signal is Fc, the local frequency of the frequency conversion unit 12A (mixer 12A1) is (n-1)×Fs/2.

### Third Example Embodiment

A third example embodiment relates to another variation of the configuration of the feedback signal forming unit. The third example embodiment relates to a case where n is an even number.

FIG. 6 is a block diagram illustrating another example of the feedback signal forming unit of the present disclosure. In FIG. 6, the feedback signal forming unit 12 includes a frequency conversion unit 12A and an image correction unit 12C.

The frequency conversion unit 12A of the third example embodiment performs frequency conversion on the frequency component that has passed through the band limiting unit 11A such that the frequency of the frequency component becomes the baseband frequency.

The image correction unit 12C performs processing of folding back the frequency component converted into the baseband frequency by the frequency conversion unit 12A in the frequency domain.

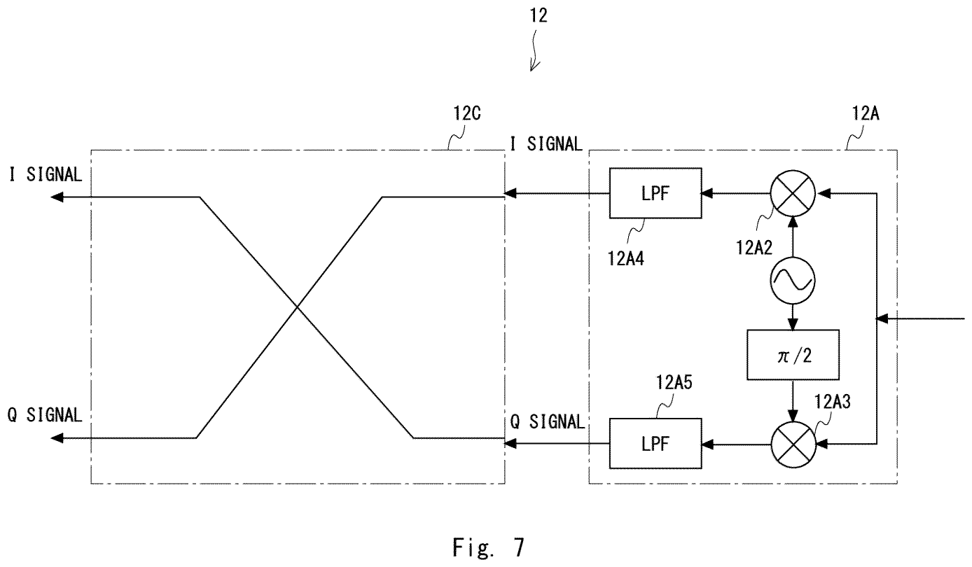

FIG. 7 is a diagram illustrating a more specific configuration of another example of the feedback signal forming unit of the present disclosure.

As illustrated in FIG. 7, the frequency conversion unit 12A of the third example embodiment is a quadrature demodulator. That is, the frequency conversion unit 12A includes frequency mixers 12A2 and 12A3 and low-pass filters 12A4 and 12A5. The frequency mixers 12A2 and 12A3 convert the frequency components that have passed through the band limiting unit 11A into baseband frequencies. The local frequency of the frequency mixer 12A2 and the local frequency of the frequency mixer 12A3 are shifted by π/2 phase from each other. The low-pass filters 12A4 and 12A5 pass frequency components corresponding to the passing band including the baseband frequency among the output signals of the frequency mixers 12A2 and 12A3. As illustrated in FIG. 7, an I signal is formed by the frequency mixer 12A2 and the low-pass filter 12A4. In addition, a Q signal is formed by the frequency mixer 12A3 and the low-pass filter 12A5.

As illustrated in FIG. 7, the image correction unit 12C has a configuration in which the I signal and the Q signal output from the frequency conversion unit 12A are interchanged with each other and output as the Q signal and the I signal, respectively.

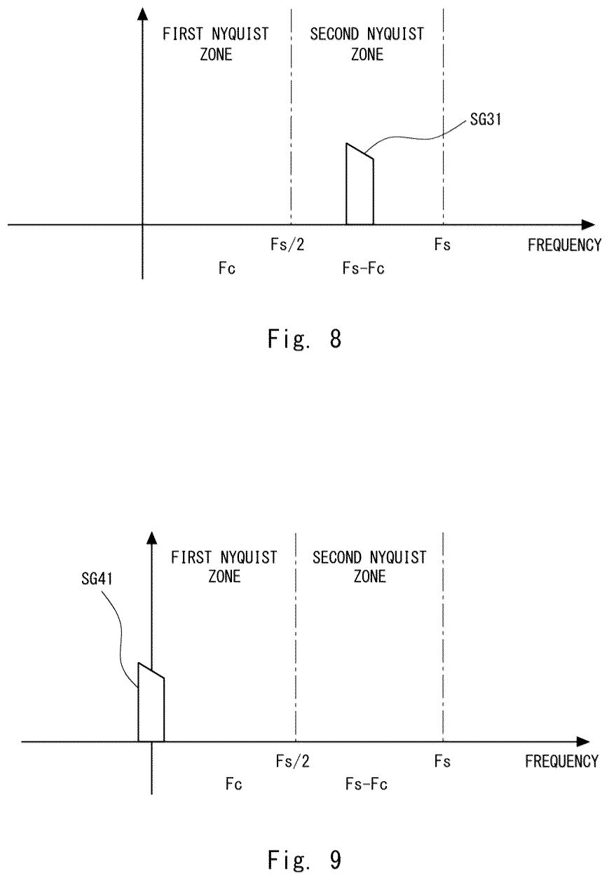

FIGS. 8, 9, and 10 are diagrams provided for explaining the feedback signal forming processing. FIGS. 8, 9, and 10 illustrate cases where n=2. The inclination of the upper side of the signal illustrated in FIGS. 8, 9, and 10 represents the frequency characteristic of the signal.

A signal SG31 illustrated in FIG. 8 is a frequency component that has passed through the band limiting unit 11A. The frequency mixers 12A2 and 12A3 convert the signal SG31 into a baseband frequency. As a result, a signal SG41 illustrated in FIG. 9 is obtained.

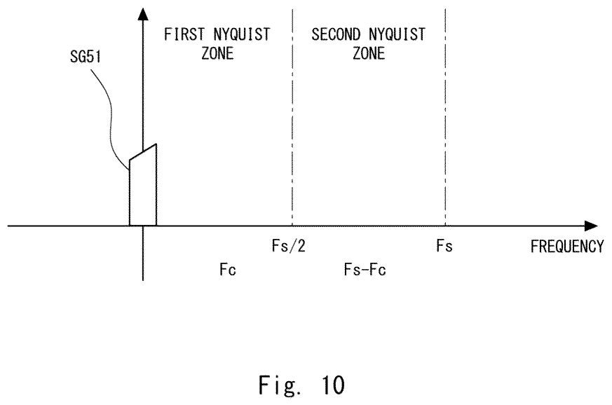

The image correction unit 12C interchanges the I signal and the Q signal of the signal SG41 with each other and outputs the Q signal and the I signal, respectively. The image correction unit 12C is illustrated as a signal SG51 in FIG. 10. That is, the frequency characteristic of the signal SG41 is inverted in the frequency domain by the processing of the image correction unit 12C, and becomes the signal SG51.

### Fourth Example Embodiment

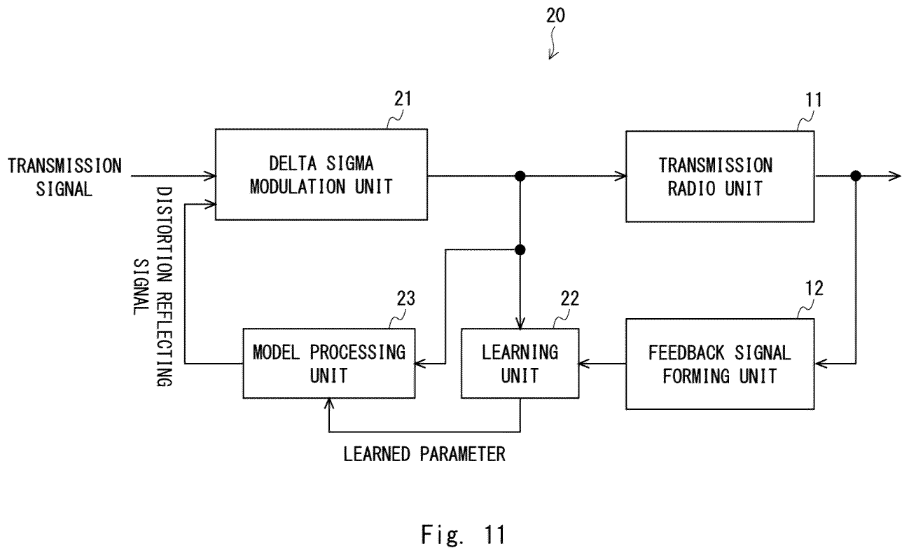

FIG. 11 is a block diagram illustrating another example of the wireless communication device of the present disclosure. In FIG. 11, the wireless communication device 20 includes a delta sigma modulation unit 21, a learning unit 22, a model processing unit 23, a transmission radio unit 11, and a feedback signal forming unit 12.

The delta sigma modulation unit 21 receives the transmission signal (analog signal) and the distortion reflecting signal output from the model processing unit 23. Then, the delta sigma modulation unit 21 forms a delta sigma modulated signal and outputs the formed delta sigma modulated signal based on the received transmission signal (analog signal) and distortion reflecting signal. For example, the delta sigma modulation unit 21 forms the above-described “distortion component signal” based on the transmission signal and the distortion reflecting signal. Then, based on the “distortion component signal”, the delta sigma modulation unit 21 forms a distortion suppressing signal for suppressing a distortion component included in a frequency component corresponding to the nth Nyquist zone in the input signal to the transmission radio unit 11 (band limiting unit 11A). Then, the delta sigma modulation unit 21 forms the transmission signal after the distortion suppression processing by superimposing the distortion suppressing signal on the transmission signal (analog signal). Then, the delta sigma modulation unit 21 quantizes the transmission signal after the distortion suppression processing to form and output a quantized signal (1 bit pulse train). This quantized signal (1 bit pulse train) corresponds to the delta sigma modulated signal described above. The configuration of the delta sigma modulation unit 21 will be described in detail later.

The model processing unit 23 includes a learned model. This learned model is a model reflecting the parameters of the distortion model learned by the learning unit 22. The model processing unit 23 receives the output signal of the delta sigma modulation unit 21 as input, and outputs a distortion reflecting signal reflecting a distortion component (alternatively, an approximate value of the distortion component) of the first Nyquist zone corresponding to the distortion component of the nth Nyquist zone in the input signal to the transmission radio unit 11 (band limiting unit 11A). The configuration (model) of the model processing unit 23 will be described in detail later.

The learning unit 22 performs learning processing of a distortion model in a learning period of the distortion model. For example, the learning unit 22 compares a distortion reflecting signal obtained by the distortion model to be learned receiving the output signal of the delta sigma modulation unit (not illustrated) and outputting based on the output signal with the feedback signal, and calculates an error between the output signal and the distortion reflecting signal. The learning unit 22 calculates a parameter of the distortion model based on the calculated error, and updates the parameter of the distortion model by the calculated parameter. The learning unit 22 repeats these processing until the learning end condition is satisfied. As a result, parameters of the learned model are obtained. The learning unit 22 reflects the learned parameter on the model of the model processing unit 23. The configuration of the learning unit 22 will be described in detail later.

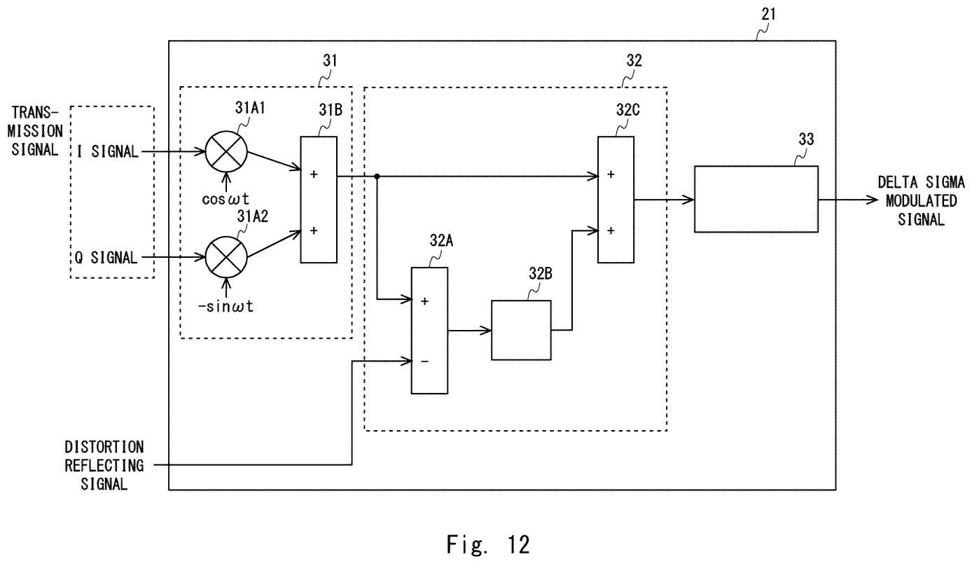

FIG. 12 is a block diagram illustrating an example of a delta sigma modulation unit of the present disclosure. The delta sigma modulation unit 21 includes an up-converter 31, a loop filter 32, and a quantizer 33.

Signals input to the delta sigma modulation unit 21 are baseband signals, and include an in-phase component signal (hereinafter referred to as an “I signal”) and a quadrature component signal (hereinafter referred to as a “Q signal”).

The up-converter 31 is a two-input one-output component. The up-converter 31 receives the I signal and the Q signal as input signals. The up-converter 31 up-converts a first signal (the I signal and the Q signal) to a desired frequency (target frequency) f0.

The up-converter 31 includes a multiplier 3 1A1, a multiplier 31A 2, and an adder 31B. The multiplier 31A1 multiplies the I signal by cosωt and outputs a multiplication result to the adder 31B. The multiplier 31A2 multiplies the Q signal by-sinωt and outputs a multiplication result to the adder 31B. Here, “cos ( )” is a cosine function, and “sin ( )” is a sine function (the same applies hereinafter). Furthermore, ω=2×π×f 0.

The adder 31B adds the multiplication result of the multiplier 31A1 and the multiplication result of the multiplier 31A2 and outputs an addition result.

The loop filter 32 is a two-input one-output element. The loop filter 32 receives the output of the up-converter 31 and the distortion reflecting signal output from the model processing unit 23 as input signals.

The loop filter 32 includes an adder 32A, a transfer function processing unit 32B, and an adder 32C.

The adder 32A adds the output of the up-converter 31 (the output of the adder 31B) and the distortion reflecting signal, and outputs the addition result to the transfer function processing unit 32B. Here, the output of the adder 32A is a difference between the output of the up-converter 31 and the distortion reflecting signal. The output of the adder 32A corresponds to a distortion component included in a frequency component corresponding to the nth Nyquist zone in the input signal to the transmission radio unit 11 (band limiting unit 11A). That is, the output of the adder 32A can be referred to as a “distortion component signal”.

The transfer function processing unit 32B applies a transfer function to the output of the adder 32A to form a distortion suppressing signal for suppressing a distortion component included in a frequency component corresponding to the nth Nyquist zone in the input signal to the transmission radio unit 11 (band limiting unit 11A). The transfer function is a function that determines the characteristic of the delta sigma modulation in the present example, and is determined based on a desired signal transfer function, noise transfer function, and the like.

The adder 32C adds the output of the up-converter 31 and the output of the transfer function processing unit 32B, and outputs the addition result to the quantizer 33. That is, the adder 32C forms the transmission signal (analog signal) after the distortion compensation processing by superimposing the distortion suppressing signal on the transmission signal (analog signal).

The quantizer 33 is a 1-bit quantizer. The quantizer 33 quantizes the output of the loop filter 32 (the output of the adder 32C) with 1 bit and outputs a delta sigma modulated signal (1 bit pulse train).

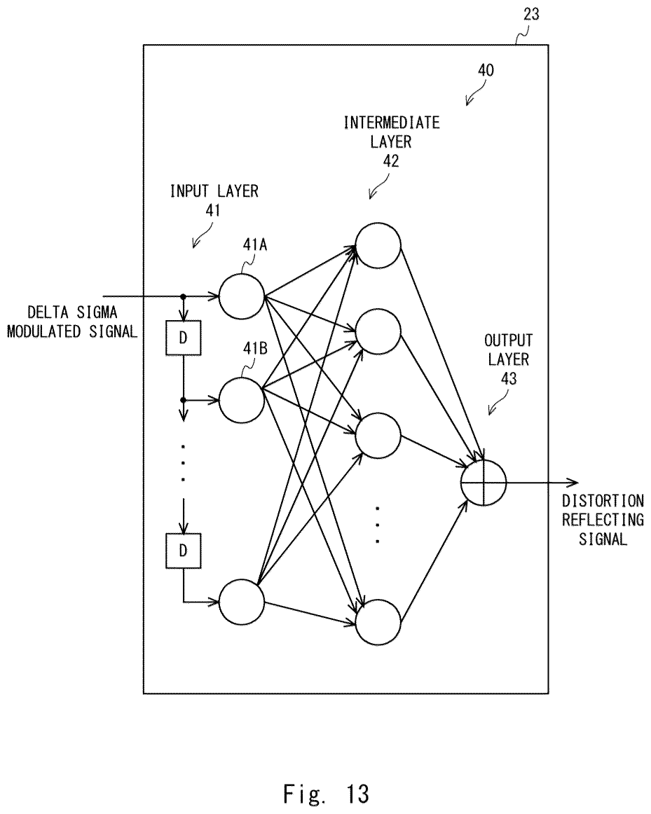

FIG. 13 is a block diagram illustrating an example of a model processing unit of the present disclosure. The model processing unit 23 includes a distortion model (neural network) 40. The distortion model 40 receives the delta sigma modulated signal as an input signal and outputs a distortion reflecting signal. As described above, the distortion reflecting signal is a signal reflecting the distortion component (alternatively, an approximate value of the distortion component) of the first Nyquist zone corresponding to the distortion component of the nth Nyquist zone in the input signal to the transmission radio unit 11 (band limiting unit 11A).

The distortion model 40 operates in accordance with parameters (learned parameters) received from the learning unit 22 and set. This parameter includes, for example, a weight and a bias. For example, if a function f in the following formula (1) is an activation function in a neural network, x is an input, w is a weight, and b is a bias.

The distortion model 40 includes an input layer 41, an intermediate layer 42, and an output layer 43. The intermediate layer 42 is one layer.

The input layer 41 includes a node 41A to which the current delta sigma modulated signal is input. Furthermore, the input layer 41 further includes a node 41B to which the past delta sigma modulated signal is input. “D” represents a delay. The output layer 43 is a linear layer having no activation function. The above-described learned parameters are reflected in the intermediate layer 42. The output layer 43 outputs the sum of the outputs of the plurality of nodes of the intermediate layer 42 as a distortion reflecting signal.

The configuration of the distortion model 40 is not limited to the configuration of FIG. 13. Nonlinear operation based on products of various generally used neural networks and input signals may be applied. For example, the intermediate layer 42 of the distortion model 40 may have a plurality of layers. That is, a multilayer neural network may be adopted as the distortion model 40.

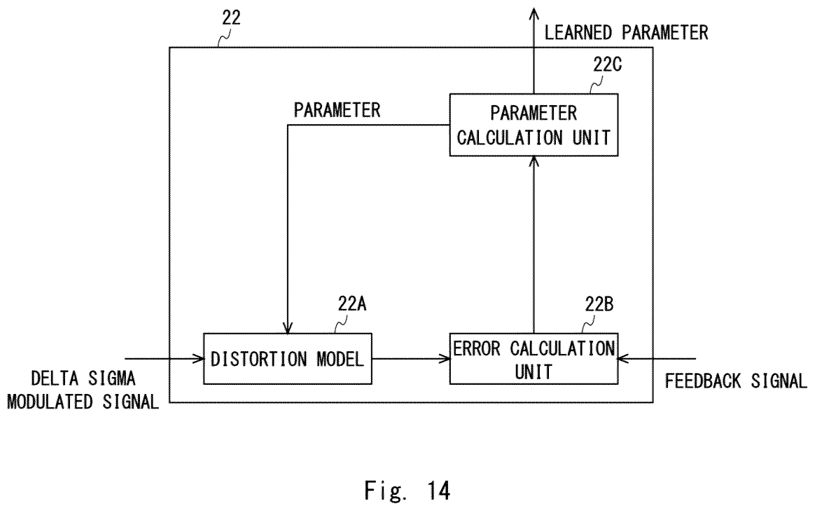

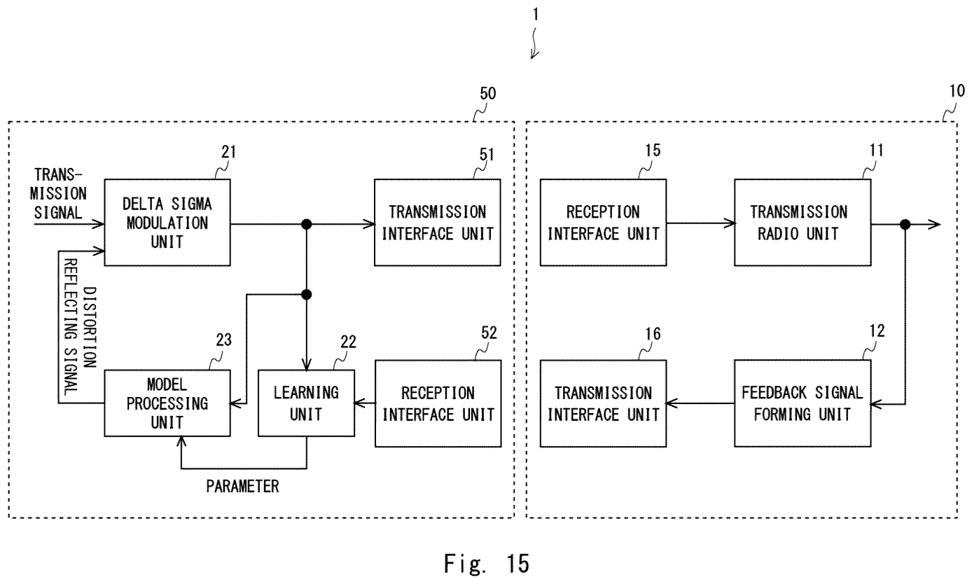

FIG. 14 is a block diagram illustrating an example of a learning unit of the present disclosure. In FIG. 14, the learning unit 22 includes a distortion model 22A, an error calculation unit 22B, and a parameter calculation unit 22C.

The distortion model 22A has the same configuration as the distortion model (neural network) 40. The distortion model 22A receives the delta sigma modulated signal as an input signal and outputs a distortion reflecting signal.

The error calculation unit 22B receives the output (distortion reflecting signal) of the distortion model 22A and the feedback signal as input signals. The error calculation unit 22B receives the output (distortion reflecting signal) of the distortion model 22A and the feedback signal as input signals. The error calculation unit 22B calculates an error (difference) between the distortion model and the feedback signal.

The parameter calculation unit 22C calculates a parameter using the above error. The parameter calculation unit 22C outputs the calculated parameter to the distortion model 22A. As a result, the parameter set to the distortion model 22A is updated by the parameter output from the parameter calculation unit 22C. The processing of the distortion model 22A, the error calculation unit 22B, and the parameter calculation unit 22C described above is repeated, and the distortion model 22A (and parameters) is learned. Then, in a case where the ending condition of learning of the distortion model 22A (and parameters) is satisfied, the parameter calculated last by the parameter calculation unit 22C is output as a learned parameter from the parameter calculation unit 22C to the model processing unit 23. As a result, learned parameters are set in the model processing unit 23.

### Fifth Example Embodiment

In the fourth example embodiment, description has been made on the assumption that the delta sigma modulation unit, the learning unit, the model processing unit, the transmission radio unit, and the feedback signal forming unit are included in one device, but the present disclosure is not limited thereto. In the fifth example embodiment, a case where a delta sigma modulation unit, a learning unit, and a model processing unit are included in one device, and a transmission radio unit and a feedback signal forming unit are included in another device will be described.

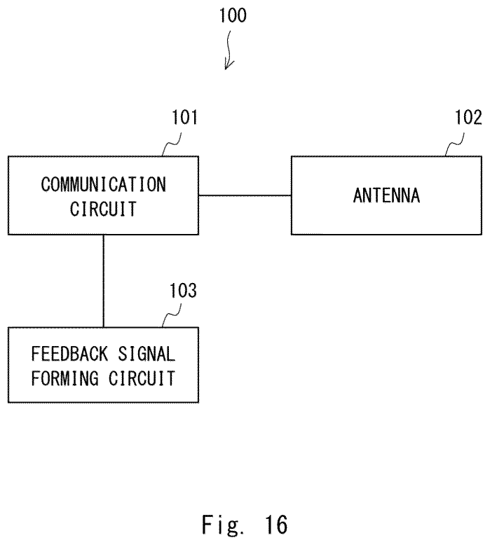

FIG. 15 is a block diagram illustrating an example of a system of the present disclosure. In FIG. 15, the system 1 includes a communication device 50 and a wireless communication device 10. The communication device 50 and the wireless communication device 10 may be, for example, wirelessly connected. Alternatively, the communication device 50 and the wireless communication device 10 may be connected by an optical cable.

The communication device 50 includes a transmission interface unit 51, a reception interface unit 52, a delta sigma modulation unit 21, a learning unit 22, and a model processing unit 23. In addition, the wireless communication device 10 includes a reception interface unit 15, a transmission interface unit 16, a transmission radio unit 11, and a feedback signal forming unit 12.

First, a case where the communication device 50 and the wireless communication device 10 are wirelessly connected will be described. The transmission interface unit 51 includes, for example, an antenna (not illustrated). The transmission interface unit 51 wirelessly transmits the delta sigma modulated signal received from the delta sigma modulation unit 21. The reception interface unit 15 receives a signal wirelessly transmitted from the transmission interface unit 51, and outputs the reception signal to the transmission wireless unit 11. That is, the input signal input to the transmission radio unit 11 is a signal received by the wireless communication device 10 after a signal delta sigma modulated by the communication device 50 is wirelessly transmitted from the communication device 50. The transmission interface unit 16 wirelessly transmits the feedback signal received from the feedback signal forming unit 12. The reception interface unit 52 receives a signal wirelessly transmitted from the transmission interface unit 16 and outputs the signal to the learning unit 22.

Next, a case where the communication device 50 and the wireless communication device 10 are optically connected will be described. That is, the communication device 50 is an optical communication device. The transmission interface unit 51 converts the delta sigma modulated signal (electrical signal) received from the delta sigma modulation unit 21 into an optical signal, and transmits the optical signal to the wireless communication device 10 via the optical transmission line. The reception interface unit 15 receives the optical signal transmitted from the transmission interface unit 51 and converts the optical signal into an electrical signal. This electrical signal is output to the transmission radio unit 11. That is, it is an electrical signal obtained by optical-electrical converting the optical signal received by the wireless communication device 10 after the signal delta sigma modulated by the communication device 50 is electro-optically converted into an optical signal and optically transmitted from the communication device 50. The transmission interface unit 16 converts a feedback signal (electrical signal) received from the feedback signal forming unit 12 into an optical signal, and transmits the optical signal to the communication device 50 via the optical transmission line. The reception interface unit 52 receives the optical signal transmitted from the transmission interface unit 16 and converts the optical signal into an electrical signal. The electrical signal is output to the learning unit 22.

### Other Example Embodiments

FIG. 16 is a diagram illustrating a configuration example of a wireless communication device. In FIG. 16, the wireless communication device 100 includes a communication circuit 101, an antenna 102, and a feedback signal forming circuit 103.

The reception interface unit 15, the transmission interface unit 16, and the transmission radio unit 11 of the wireless communication device 10 of the first to fifth example embodiments are achieved by a communication circuit 101. In addition, the feedback signal forming unit 12 of the wireless communication device 10 of the first to fifth example embodiments is achieved by a feedback signal forming circuit 103.

Alternatively, each of the reception interface unit 15, the transmission interface unit 16, the transmission radio unit 11, and the feedback signal forming unit 12 of the wireless communication device 10 of the first to fifth example embodiments may be achieved by dedicated hardware.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with at least one of embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

Some or all of the above example embodiments can also be described as the following Supplementary Notes, but are not limited to the following.

### Supplementary Note 1

A wireless communication device including,
a band limiting unit for passing a frequency component corresponding to an nth (n is an integer equal to or greater than two) Nyquist zone in an input signal based on a signal delta sigma modulated by a delta sigma modulation unit, and
a feedback signal forming unit that includes a frequency conversion unit for converting a frequency component that has passed through the band limiting unit into a frequency component with a frequency corresponding to a first Nyquist zone, and forms a feedback signal used for learning of a distortion model to which an output signal of the delta sigma modulation unit is input and outputs a distortion reflecting signal reflecting a distortion component of the first Nyquist zone corresponding to a distortion component of an nth Nyquist zone in the input signal, based on the frequency component that has passed through the band limiting unit.

### Supplementary Note 2

The wireless communication device according to supplementary note 1, in which
if n is an even number, the frequency conversion unit performs frequency conversion on a frequency component that has passed through the band limiting unit such that a frequency of an image component in the frequency component becomes a target frequency of the first Nyquist zone, and
the feedback signal forming unit includes a second band limiting unit that passes a frequency component corresponding to a passing band including the target frequency of the frequency component subjected to frequency conversion by the frequency conversion unit.

### Supplementary Note 3

The wireless communication device according to supplementary note 2, in which in a case where a sample rate of the delta sigma modulation is Fs and a carrier frequency of a first Nyquist zone of the delta sigma modulated signal is Fc, a local frequency of the frequency conversion unit is n×Fs.

### Supplementary Note 4

The wireless communication device according to supplementary note 1, in which in a case where the n is an odd number, a sample rate of the delta sigma modulation is Fs and a carrier frequency of a first Nyquist zone of the delta sigma modulated signal is Fc, a local frequency of the frequency conversion unit is (n-1)×Fs/2.

### Supplementary Note 5

The wireless communication device according to supplementary note 1, in which in a case where the n is an even number, the feedback signal forming unit further includes an image correction unit that is provided at an output stage of the frequency conversion unit and turns back, in a frequency domain, a frequency component converted into a frequency corresponding to the first Nyquist zone by the frequency conversion unit.

### Supplementary Note 6

The wireless communication device according to supplementary note 5, in which
the frequency conversion unit is a quadrature demodulator provided at an input stage of the image correction unit, and
the image correction unit interchanges I signal and Q signal output from the quadrature demodulator with each other and outputs as a Q signal and an I signal.

### Supplementary Note 7

The wireless communication device according to supplementary note 6, in which
the quadrature demodulator includes two frequency mixers and two low-pass filters, and
each of the two frequency mixers converts a frequency component that has passed through the band limiting unit into a baseband frequency.

### Supplementary Note 8

The wireless communication device according to any one of supplementary notes 1 to 7, in which
the input signal is a signal received by the wireless communication device after a signal delta sigma modulated by another wireless communication device is wirelessly transmitted from the other wireless communication device, and
the feedback signal is used for learning the distortion model in the other wireless communication device.

### Supplementary Note 9

The wireless communication device according to any one of supplementary notes 1 to 7, in which
the input signal is an electrical signal obtained by optical-electrical converting an optical signal received by the wireless communication device after a signal delta sigma modulated by an optical communication device is electro-optically converted into an optical signal and optically transmitted from the optical communication device, and
the feedback signal is used for learning the distortion model in the optical communication device.

### Supplementary Note 10

A method executed by a feedback signal forming device, the method including
executing band limiting processing of passing a frequency component corresponding to an nth (n is an integer equal to or greater than two) Nyquist zone in an input signal based on a signal delta sigma modulated in delta sigma modulation processing, and
executing feedback signal forming processing of forming, based on the passed frequency component, a feedback signal used for learning of a distortion model to which an output signal of the delta sigma modulation processing is input and that outputs a distortion reflecting signal reflecting a distortion component of a first Nyquist zone corresponding to a distortion component of the nth Nyquist zone in the input signal,
in which the feedback signal forming processing includes frequency conversion processing of converting the passed frequency component into a frequency component with a frequency corresponding to the first Nyquist zone.

### Supplementary Note 11

The method according to supplementary note 10, in which
if n is an even number, the frequency conversion processing includes performing frequency conversion on a frequency component that has passed through the band limiting unit such that a frequency of an image component in the frequency component becomes a target frequency of the first Nyquist zone, and
the feedback signal forming processing includes passing a frequency component corresponding to a passing band including the target frequency of the frequency component subjected to frequency conversion in the frequency conversion processing.

### Supplementary Note 12

The method according to supplementary note 11, in which in a case where a sample rate of the delta sigma modulation is Fs and a carrier frequency of a first Nyquist zone of the delta sigma modulated signal is Fc, a local frequency of the frequency conversion processing is n ×Fs.

### Supplementary Note 13

The method according to supplementary note 10, in which in a case where the n is an odd number, a sample rate of the delta sigma modulation is Fs and a carrier frequency of a first Nyquist zone of the delta sigma modulated signal is Fc, a local frequency of the frequency conversion processing is (n-1)×Fs/2.

### Supplementary Note 14

The method according to supplementary note 10, in which in a case where the n is an even number, the feedback signal forming processing further includes an image correction processing executed after the frequency conversion processing and provided to turn back, in a frequency domain, a frequency component converted into a frequency corresponding to the first Nyquist zone by the frequency conversion processing.

### Supplementary Note 15

The method according to supplementary note 14, in which
the frequency conversion processing is quadrature demodulation processing executed before the image correction processing, and
the image correction processing includes interchanging an I signal and a Q signal output from the quadrature demodulation processing with each other and outputting as a Q signal and an I signal.

### Supplementary Note 16

The method according to supplementary note 15, in which
the quadrature demodulation processing is executed by two frequency mixers and two low-pass filters, and
each of the two frequency mixers converts a frequency component that has passed through the band limiting processing into a baseband frequency.

### Supplementary Note 17

The method according to any one of supplementary notes 10 to 16, in which
the input signal is a signal received by the wireless communication device after a signal delta sigma modulated by another wireless communication device is wirelessly transmitted from the other wireless communication device, and
the feedback signal is used for learning the distortion model in the other wireless communication device.

### Supplementary Note 18

The method according to any one of supplementary notes 10 to 16, in which
the input signal is an electrical signal obtained by optical-electrical converting an optical signal received by the wireless communication device after a signal delta sigma modulated by an optical communication device is electro-optically converted into an optical signal and optically transmitted from the optical communication device, and
the feedback signal is used for learning the distortion model in the optical communication device.

What is claimed is:

1. A wireless communication device comprising:
a communication circuit; and
a feedback signal forming circuit connected to the communication circuit, wherein
the communication circuit is configured to execute band limiting processing of passing a frequency component corresponding to an nth (n is an integer equal to or greater than two) Nyquist zone in an input signal based on a signal delta sigma modulated in delta sigma modulation processing; and
the feedback signal forming circuit is configured to execute feedback signal forming processing including frequency conversion processing of converting a frequency component that has passed the band limiting processing into a frequency component with a frequency corresponding to a first Nyquist zone, the feedback signal forming processing forming, based on the frequency component that has passed the band limiting processing, a feedback signal used for learning of a distortion model to which an output signal of the delta sigma modulation processing is input and that outputs a distortion reflecting signal reflecting a distortion component of the first Nyquist zone corresponding to a distortion component of the nth Nyquist zone in the input signal.

2. The wireless communication device according to claim 1, wherein
if n is an even number, the frequency conversion processing performs frequency conversion on a frequency component that has passed through the band limiting processing such that a frequency of an image component in the frequency component becomes a target frequency of the first Nyquist zone, and
the feedback signal forming processing includes second band limiting processing of passing a frequency component corresponding to a passing band including the target frequency of the frequency component subjected to frequency conversion by the frequency conversion processing.

3. The wireless communication device according to claim 2, wherein in a case where a sample rate of the delta sigma modulation is Fs and a carrier frequency of a first Nyquist zone of the delta sigma modulated signal is Fc, a local frequency of the frequency conversion processing is n×Fs.

4. The wireless communication device according to claim 1, wherein in a case where the n is an odd number, a sample rate of the delta sigma modulation is Fs and a carrier frequency of a first Nyquist zone of the delta sigma modulated signal is Fc, a local frequency of the frequency conversion processing is (n-1)×Fs/2.

5. The wireless communication device according to claim 1, wherein in a case where the n is an even number, the feedback signal forming processing further includes an image correction processing provided at an output stage of the frequency conversion processing to turn back, in a frequency domain, a frequency component converted into a frequency corresponding to the first Nyquist zone in the frequency conversion processing.

6. The wireless communication device according to claim 5, wherein
the frequency conversion processing is quadrature demodulation processing at an input stage of the image correction processing, and
the image correction processing includes interchanging an I signal and a Q signal output from the quadrature demodulation processing with each other and outputting as a Q signal and an I signal.

7. The wireless communication device according to claim 6, wherein
the quadrature demodulation processing is performed by two frequency mixers and two low-pass filters included in the feedback signal forming circuit; and
each of the two frequency mixers converts a frequency component that has passed through the band limiting processing into a baseband frequency.

8. The wireless communication device according to claim 1, wherein
the input signal is a signal received by the wireless communication device after a signal delta sigma modulated by another wireless communication device is wirelessly transmitted from the other wireless communication device; and
the feedback signal is used for learning the distortion model in the other wireless communication device.

9. The wireless communication device according to claim 1, wherein
the input signal is an electrical signal obtained by optical-electrical converting an optical signal received by the wireless communication device after a signal delta sigma modulated by an optical communication device is electro-optically converted into an optical signal and optically transmitted from the optical communication device; and
the feedback signal is used for learning the distortion model in the optical communication device.

10. A method executed by a feedback signal forming device, the method comprising:
executing band limiting processing of passing a frequency component corresponding to an nth (n is an integer equal to or greater than two) Nyquist zone in an input signal based on a signal delta sigma modulated in delta sigma modulation processing; and
executing feedback signal forming processing of forming, based on the passed frequency component, a feedback signal used for learning of a distortion model to which an output signal of the delta sigma modulation processing is input and that outputs a distortion reflecting signal reflecting a distortion component of a first Nyquist zone corresponding to a distortion component of the nth Nyquist zone in the input signal,
wherein the feedback signal forming processing includes frequency conversion processing of converting the passed frequency component into a frequency component with a frequency corresponding to the first Nyquist zone.
